(19) United States
(12) Patent Application Publication
(10) Pub. No.: US 2015/0137158 A1
(43) Pub. Date: May 21, 2015

(54) LED PACKAGE FRAME AND LED PACKAGE STRUCTURE

(71) Applicant: LEXTAR ELECTRONICS CORPORATION, Hsinchu (TW)

(72) Inventors: Tsung-Han LI, New Taipei City (TW); Cheng-Ping CHANG, Hsinchu City (TW)

(73) Assignee: LEXTAR ELECTRONICS CORPORATION, Hsinchu (TW)

(21) Appl. No.: 14/281,771

(22) Filed: May 19, 2014

(30) Foreign Application Priority Data
Nov. 20, 2013 (TW) 102142196

(51) Int. Cl. H01L 33/62; H01L 33/54; H01L 33/50

(52) U.S. Cl. CPC H01L 33/62; H01L 33/507; H01L 33/54
USPC 257/98; 257/676

(57) ABSTRACT

A light-emitting diode (LED) package frame is provided, including a leadframe and an insulating member. The leadframe includes a first electrode and a second electrode separated from each other. The insulating member is disposed between the first electrode and the second electrode for insulation between the first and second electrodes, including a first protrusion and a second protrusion. The coefficient of thermal expansion of the insulating member is greater than that of the leadframe. Specifically, the first electrode and the second electrode respectively include a first recess and a second recess which abut the insulating member. The first protrusion and the second protrusion are respectively engaged with the first recess and the second recess.

### CROSS REFERENCE TO RELATED APPLICATIONS

The present application claims priority of Taiwan Patent Application No. 102142196, filed on Nov. 20, 2013, the entirety of which is incorporated by reference herein.

### BACKGROUND OF THE INVENTION

1. Field of the Invention

The present application relates to a light-emitting diode (LED) package structure, and in particular to an LED package frame thereof.

2. Description of the Related Art

Referring to FIG. 1, a conventional light-emitting diode (LED) package structure 1 includes an LED package frame 10, at least an LED chip E, and an encapsulant P covering the LED chip E. The LED package frame 10 includes a leadframe 12 electrically connected to the LED chip E (the wires for electrical connection are not shown in FIG. 1), a cup-shaped body 14, and an insulating member 16 for insulation between the electrodes 12A and 12B of the leadframe 12, wherein the electrodes 12A and 12B have different electrical properties.

Owing to the leadframe 12 and the insulating member 16 made of two different materials (for example, the leadframe 12 may comprise metal and the insulating member 16 may comprise plastic), the coefficients of thermal expansion thereof are different. As such, the leadframe 12 and the insulating member 16 may separate from each other and generate a gap G therebetween during heating of the LED package structure 1, and thus the encapsulant P may easily leak out of the LED package structure 1 from the gap G. Furthermore, the follow-on processes and illumination efficiency of the LED package structure 1 may be adversely affected.

### BRIEF SUMMARY OF THE INVENTION

In view of the aforementioned known problems, an objective of the invention is to provide a light-emitting diode (LED) package structure and an LED package frame thereof, which can effectively suppress leakage of the encapsulant.

An embodiment of the invention provides an LED lead package comprising a leadframe, a cup-shaped body, and a first insulating member. The leadframe includes a first electrode and a second electrode separated from each other. The cup-shaped body covers the first electrode and the second electrode, and exposes a portion of the first electrode and a portion of the second electrode to form a die-attachment surface and a bottom surface opposite to each other. The first insulating member is disposed between the first electrode and the second electrode for insulation between the first and second electrodes, including a first protrusion and a second protrusion. The coefficient of thermal expansion of the first insulating member is greater than that of the leadframe. Specifically, the first electrode and the second electrode respectively include a first recess and a second recess which abut the insulating member. The first protrusion and the second protrusion are respectively engaged with the first recess and the second recess.

Another embodiment of the invention provides an LED package structure comprising the LED package frame and an LED chip disposed on the die-attachment surface.

### BRIEF DESCRIPTION OF THE DRAWINGS

The invention can be more fully understood by reading the subsequent detailed description and examples with references made to the accompanying drawings, wherein:

FIG. 1 is a sectional view of a conventional light-emitting diode (LED) package structure; and

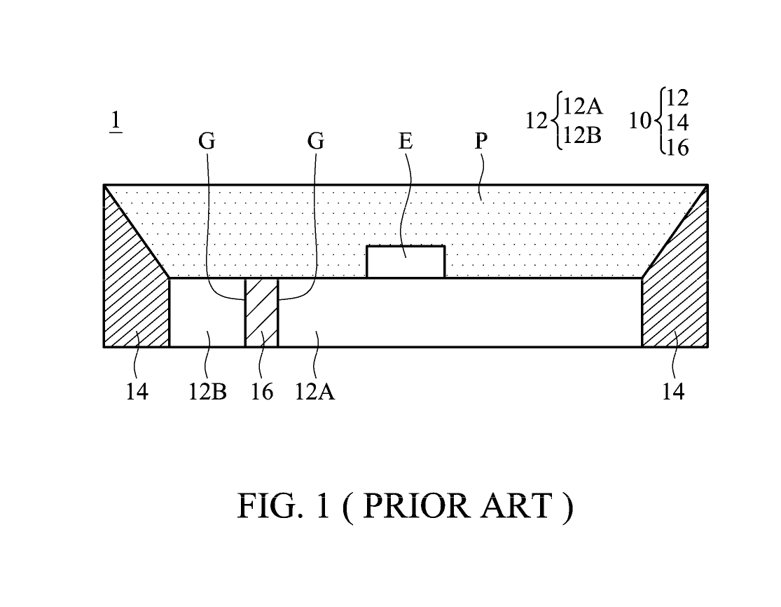

FIG. 2 is a sectional view of an LED package structure and an LED package frame thereof according to an embodiment of the invention.

### DETAILED DESCRIPTION OF THE INVENTION

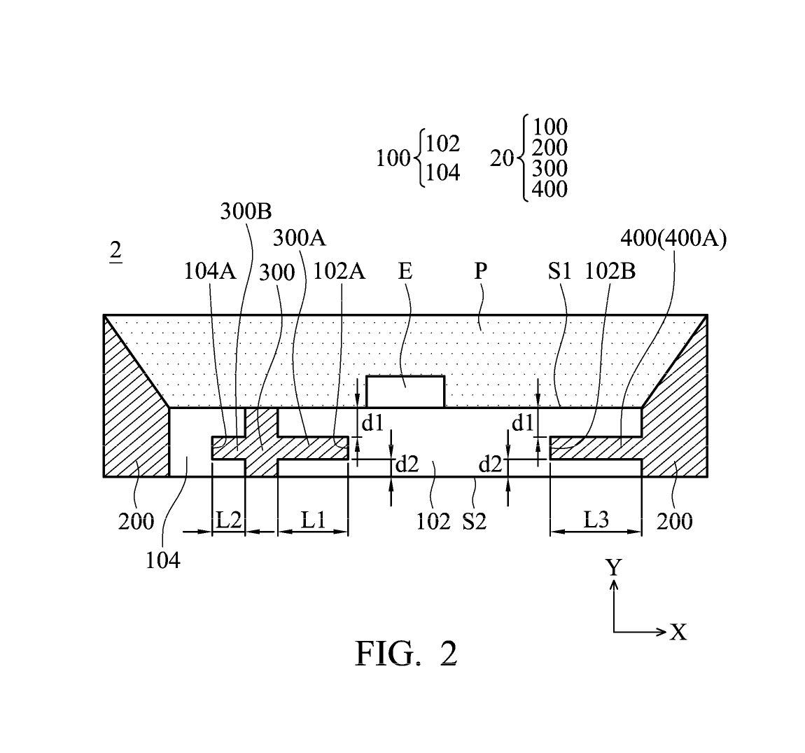

Referring to FIG. 2, a light-emitting diode (LED) package structure 2 according to an embodiment of the invention includes an LED package frame 20, at least an LED chip E, and a wavelength converting structure P. The LED chip E is disposed on the LED package frame 20. The wavelength converting structure P is also disposed on the LED package frame 20 and covers the LED chip E. In this embodiment, the wavelength converting structure P may be an encapsulant with phosphor powder disposed therein.

As shown in FIG. 2, the LED package frame 20 primarily includes a leadframe 100, a cup-shaped body 200, and a first insulating member 300. The leadframe 100 includes a first electrode 102 and a second electrode 104 separated from each other. The cup-shaped body 200 covers the outside of the first electrode 102 and the second electrode 104, and exposes a portion of the first electrode 102 and a portion of the second electrode 104 to form a die-attachment surface S1 and a bottom surface S2 opposite to each other. In addition, the first insulating member 300 is disposed between the first electrode 102 and the second electrode 104 for insulation between the first and second electrodes 102 and 104. Specifically, the LED chip E is disposed on the die-attachment surface S1 of the first electrode 102, and the encapsulant P is filled in the cup-shaped body 200 and covers the LED chip E.

Still referring to FIG. 2, the first electrode 102 and the second electrode 104 respectively include a first recess 102A and a second recess 104A formed on two side walls thereof which abut the first insulating member 300. The first recess 102A and the second recess 104A are extended along the X-axis and toward the interior of the first electrode 102 and the second electrode 104, respectively. In addition, the first recess 102A/the second recess 104A and the die-attachment surface S1 have a distance d1 therebetween along the Y-axis, and the first recess 102A/the second recess 104A and the bottom surface S2 have a distance d2 therebetween along the Y-axis. Accordingly, the first insulating member 300 includes a first protrusion 300A and a second protrusion 300B. The first protrusion 300A and the second protrusion 300B are respectively extended along X-axis and protrude from the first insulating member 300. The first protrusion 300A and the second protrusion 300B may be engaged with the first recess 102A and the second recess 104A, respectively. As shown in FIG. 2, the first insulating member 300 of this embodiment is a crisscross-shaped in cross-section view perpendicular to the bottom surface S2.

In this embodiment, the first electrode 102 further includes a third recess 102B formed on a side thereof, opposite to the first recess 102A and adjacent to the cup-shaped body 200. Similarly, the third recess 102B is also extended along X-axis and toward the interior of the first electrode 102. The third recess 102B and the die-attachment surface S1 have the distance d1 therebetween along the Y-axis, and the third recess 102B and the bottom surface S2 have the distance d2 therebetween along the Y-axis. That is, two recesses are formed on opposite side walls of the first electrode 102. Accordingly, the LED package frame 20 may further include a second insulating member 400 having a third protrusion 400A engaged between the third recess 102B and the cup-shaped body 200.

Note that the first insulating member 300 and/or the second insulating member 400 may comprise Polyphthalamide (PPA), Polyamide-6T (PA6T), Polyamide-9T (PA9T), Polycyclohexanediol terephthalate (PCT), Epoxy Molding Compound (EMC), or a combination thereof. Specifically, the first insulating member 300 and/or the second insulating member 400 can be formed by injection molding. In some embodiments, the cup-shaped body 200 of the LED package frame 20, the first insulating member 300, and the second insulating member 300 may comprise the same material and are integrally formed in one-piece. In addition, the leadframe 100 may comprise copper, silver, or a combination thereof.

By selecting the first insulating member 300, the second insulating member 300, and the leadframe 100 with the aforementioned materials, the coefficients of thermal expansion of the first and second insulating members 300 and 400 are greater than the leadframe 100. Moreover, owing to the engagement between the “protrusions” of the first and second insulating members 300 and 400 and the “recesses” of the first and second electrodes 102 and 104, the first and second insulating members 300 and 400 and the leadframe 100 can be tightly fixed to each other during heating of the LED package structure 2. Therefore, gaps between the first and second insulating members 300 and 400 and the leadframe 100 can be avoided, thus preventing leakage of the encapsulant P from the LED package structure 2.

Additionally, by increasing the lengths L1, L2, and L3 of the first, second, and third protrusions 300A, 300B, and 400A (i.e. the depths of the first, second, and third recesses 102A, 104A, and 102B), the leakage path of the encapsulant P and the invasion path of the external steam can also be extended, and thus the reliability of the LED package structure 2 is improved. In this embodiment, the length L1 of the first protrusion 300A and/or the length L3 of the third protrusion 300A exceed the length L2 of the second protrusion 300B.

As mentioned above, the invention provides an LED package frame and an LED package structure, in which the leadframe forms several recesses therein, and the insulating members are formed by injection molding and filled in the recesses. Since the coefficients of thermal expansion of the insulating members are greater than the leadframe, the gaps between the leadframe and the insulating members can be sealed after the heating process. Therefore, leakage of the encapsulant can be prevented and the reliability of the LED package structure can be improved.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light-emitting diode (LED) package frame, comprising:
a leadframe, including a first electrode and a second electrode separated from each other;
a cup-shaped body, covering the first electrode and the second electrode, and exposing a portion of the first electrode and a portion of the second electrode to form a die-attachment surface and a bottom surface which are opposite to each other; and
a first insulating member, disposed between the first electrode and the second electrode for insulation between the first and second electrodes, and the coefficient of thermal expansion of the first insulating member is greater than that of the leadframe;
wherein the first insulating member includes a first protrusion and a second protrusion, and the first electrode and the second electrode respectively include a first recess and a second recess which abut the first insulating member, wherein the first protrusion and the second protrusion are respectively engaged with the first recess and the second recess.

2. The LED package frame as claimed in claim 1, wherein the first electrode further includes a third recess opposite to the first recess and adjacent to the cup-shaped body, and the LED package frame further comprises a second insulating member including a third protrusion engaged between the third recess and the cup-shaped body, wherein the coefficient of thermal expansion of the second insulating member is greater than that of the leadframe.

3. The LED package frame as claimed in claim 2, wherein the first insulating member and/or the second insulating member are formed by injection molding.

4. The LED package frame as claimed in claim 2, wherein the length of the first protrusion and/or the length of the third protrusion exceed that of the second protrusion.

5. The LED package frame as claimed in claim 1, wherein the first insulating member is a crisscross-shaped in cross-section view perpendicular to the bottom surface.

6. The LED package frame as claimed in claim 2, wherein the first insulating member and/or the second insulating member comprise PPA, PA6T, PA9T, PCT, EMC, or a combination thereof.

7. The LED package frame as claimed in claim 1, wherein the leadframe comprises copper, silver, or a combination thereof.

8. An LED package structure, comprising:
the LED package frame as claimed in claim 1; and
an LED chip, disposed on the die-attachment surface.

9. The LED package structure as claimed in claim 8, further comprising a wavelength converting structure disposed on the LED chip.

10. The LED package structure as claimed in claim 9, wherein the wavelength converting structure comprises an encapsulant with phosphor powder disposed therein, filled in the cup-shaped body and covering the LED chip.
